(19) United States
(12) Patent Application Publication
(10) Pub. No.: US 2026/0011669 A1
(43) Pub. Date: Jan. 8, 2026

(54) PASS-THROUGH POWER DELIVERY FOR LOGIC-ON-TOP SEMICONDUCTOR SYSTEMS

(71) Applicant: Micron Technology, Inc., Boise, ID (US)

(72) Inventors: James Brian Johnson, Boise, ID (US); Ameen D. Akel, Rancho Cordova, ID (US); Brent Keeth, Boise, ID (US); Amy Rae Griffin, Boise, ID (US); Fuad Badrieh, Boise, ID (US)

(21) Appl. No.: 19/248,133

(22) Filed: Jun. 24, 2025

Related U.S. Application Data
(60) Provisional application No. 63/668,679, filed on Jul. 8, 2024.

(51) Int. Cl. H01L 23/00; H01L 23/367; H01L 23/48; H01L 23/528; H01L 25/18; H10B 80/00; H10D 80/30

(52) U.S. Cl. CPC H01L 24/08; H01L 23/3677; H01L 23/481; H01L 23/5286; H01L 24/80; H01L 25/18; H10B 80/00; H10D 80/30; H01L 2224/08145; H01L 2224/08225; H01L 2224/80895; H01L 2224/80896; H01L 2225/06524; H01L 2225/06544; H01L 2225/06589; H01L 2924/1431; H01L 2924/14361

(57) ABSTRACT

Methods, systems, and devices for pass-through power delivery for logic-on-top semiconductor systems are described. A semiconductor system may be configured with a two-dimensional pattern of power delivery conductors that pass through semiconductor components of a stack (e.g., through one or more memory stacks), providing a more-distributed delivery of power to a logic component bonded with the stack. The power delivery conductors may include through-substrate vias that bypass circuitry of the stack, and thus may be allocated for providing power to the logic component. Such techniques may be combined with a redistribution component, such as a package substrate or interposer (e.g., opposite the logic component in the heterogeneous stack), which may include redistribution conductors that convert from relatively fewer interconnections at a surface of the semiconductor system (e.g., for solder interconnection) to relatively more interconnections at a surface bonded with the stack (e.g., for hybrid bonding interconnection).

### CROSS REFERENCE

The present application for patent claims priority to U.S. Provisional Patent Application No. 63/668,679 by Johnson et al., entitled “PASS-THROUGH POWER DELIVERY FOR LOGIC-ON-TOP SEMICONDUCTOR SYSTEMS,” filed Jul. 8, 2024, which is assigned to the assignee hereof, and which is expressly incorporated by reference in its entirety herein.

### TECHNICAL FIELD

The following relates to one or more semiconductor systems, including pass-through power delivery for logic-on-top semiconductor systems.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports pass-through power delivery for logic-on-top semiconductor systems in accordance with examples as disclosed herein.

FIG. 2 shows an example of a system that supports pass-through power delivery for logic-on-top semiconductor systems in accordance with examples as disclosed herein.

FIG. 3 through 5 show examples of systems that support pass-through power delivery for logic-on-top semiconductor systems in accordance with examples as disclosed herein.

FIGS. 6 and 7 show flowcharts illustrating methods that support pass-through power delivery for logic-on-top semiconductor systems in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some semiconductor systems, a stack of memory dies (e.g., memory chips, a memory stack, of an HBM or 3D stacked memory system) may be bonded on top of a logic component (e.g., a logic device, a logic die, a processing chip) in a heterogeneous stack (e.g., 3D stack including different die types). However, placing a relatively high-power logic component at or near the bottom of a heterogeneous stack may result in thermal challenges, because a thermal impedance of the memory dies may trap heat generated by the logic component. For example, heat generated by a logic component may be rejected (e.g., transferred) through memory dies to a heat sink (e.g., a cold plate) at another end of the stack, resulting in relatively high temperature gradient and peak temperature (e.g., at or near the logic component). In some cases, thermal effects for heterogeneous stacks may be mitigated by placing a component with a relatively high thermal output (e.g., a relatively substantial heat source), such as a logic component, as an upper device (e.g., opposite a system substrate or installation surface) for closer integration with a heat sink. In some cases, placing a logic component over a stack of memory dies may be referred to as a Logic-on-Top (LoT) configuration. However, LoT configurations may be associated with challenges for providing power to a logic component, particularly if an integration with memory dies increases a lateral distance (e.g., using one or more redistribution layers, around functional circuitry of the memory dies) over which power is conveyed to distributed circuitry of the logic component.

In accordance with examples as disclosed herein, a semiconductor system (e.g., in a LoT configuration) may be configured with a two-dimensional pattern of power delivery conductors that pass through semiconductor components of a stack (e.g., through one or more memory stacks, between functional circuitry of the stack), providing a more-distributed delivery of power to a logic component (e.g., to one or more processors of a processing system, such as one or more GPUs) bonded with the stack. The power delivery conductors may include through-substrate vias (TSVs) that bypass circuitry of the stack (e.g., bypassing transistors or other circuitry of a memory stack), and thus may be allocated to (e.g., dedicated to) providing power to the logic component. Such techniques may be combined with a redistribution component, such as a package substrate or interposer (e.g., opposite the logic component in the heterogeneous stack), which may include conductors (e.g., redistribution conductors, conductors of a redistribution layer) that convert from relatively fewer interconnections (e.g., solder balls, at a relatively coarse pitch) at a surface of the semiconductor system to relatively more interconnections (e.g., fusion contacts, hybrid bonding contacts, at a relatively finer pitch) at a surface bonded with the stack that support the two-dimensional pattern of power delivery conductors. In some examples, at least some of the dies of a stack (e.g., of a memory stack) may each include one or more memory banks, each of which may include memory arrays and bank logic operable for accessing the memory arrays. In various implementations, a two-dimensional pattern of power delivery conductors (e.g., TSVs) may include conductors formed between the memory banks, or between the memory arrays and bank logic of one or more memory banks, or various combinations thereof. Thus, in accordance with these and other examples, power delivery may be distributed through the dies of a stack, thereby improving power distribution to a logic component in a LOT configuration by reducing a lateral distance for delivering power to distributed components of the logic component and reducing accompanying losses and distribution complexity.

In addition to applicability in memory systems as described herein, techniques for pass-through power delivery for logic-on-top semiconductor systems may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by distributing power delivery vias across a stack of semiconductor components (e.g., memory dies), reducing a lateral dimension of conductors to provide power to distributed circuit elements of a logic die (e.g., including one or more processors, such as one or more processing cores). Such techniques may support a relatively high power consumption for operations of the logic die, while providing the logic die with a more-direct heat rejection path (e.g., opposite the stack of semiconductor components), which may support improved temperature uniformity, higher power density, higher processing density, improved processing speed, and overall improvements to user experience, among other benefits.

Features of the disclosure are illustrated and described in the context of systems (e.g., semiconductor systems) and architectures. Features of the disclosure are further illustrated and described in the context of flowcharts (e.g., illustrating one or more methods of forming a semiconductor system).

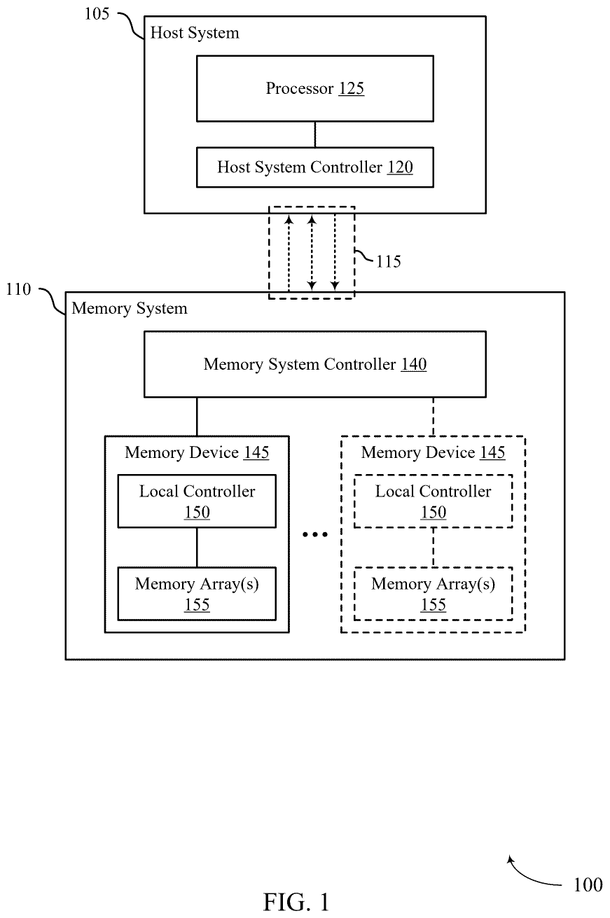

FIG. 1 shows an example of a system 100 that supports pass-through power delivery for logic-on-top semiconductor systems in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies (e.g., one or more memory stacks). In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a stacked semiconductor system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some examples of a system 100 or portion thereof, a stack of memory dies (e.g., memory chips, a memory stack, of a memory system 110, of an HBM or 3D stacked memory system) may be bonded on top of a logic component (e.g., a logic device, a logic die, a processing chip, of a memory system 110, including at least a portion of a memory system controller 140, of a host system 105, including a processor 125) in a heterogeneous stack (e.g., 3D stack including different die types). However, placing a relatively high-power logic component at or near the bottom of a heterogeneous stack may result in heat rejection challenges, because a thermal impedance of the memory dies may trap heat generated by the logic component. In some cases, thermal effects for heterogeneous stacks may be mitigated by placing a component with a relatively high thermal output (e.g., a relatively substantial heat source), such as a logic component, as an upper device (e.g., opposite a system substrate or installation surface) for closer integration with a heat sink. In some cases, placing a logic component over a stack of memory dies may be referred to as a Logic on Top (LoT) configuration. However, LoT configurations may be associated with challenges for providing power to a logic component, particularly if an integration with memory dies increases a lateral distance (e.g., using one or more redistribution layers) over which power is conveyed to distributed circuitry of the logic component. In accordance with examples as disclosed herein, a semiconductor system (e.g., at least a portion of a system 100, in a LOT configuration) may be configured with a two-dimensional pattern of power delivery conductors that pass through semiconductor components of a stack (e.g., through one or more memory stacks), providing a more-distributed delivery of power to a logic component (e.g., to one or more processors of a processing system, such as one or more GPUs) bonded with the stack.

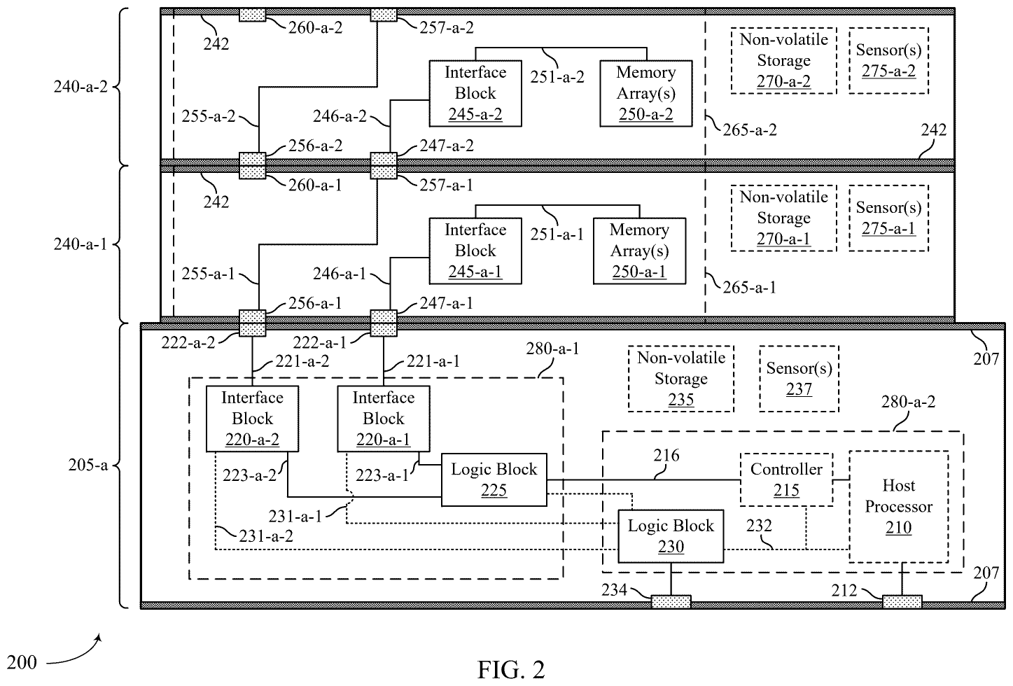

FIG. 2 shows an example of a system 200 (e.g., a semiconductor system, a system of coupled semiconductor dies, an HBM system, a 3D stacked memory system) that supports pass-through power delivery for logic-on-top semiconductor systems in accordance with examples as disclosed herein. The system 200 illustrates an example of a die 205 (e.g., a dic 205-a, a semiconductor die, a logic die, a processor die, a host die, a logic unit) that is coupled with one or more dies 240 (e.g., dies 240-a-1 and 240-a-2, semiconductor dies, memory dies, array dies, memory units, of a memory stack). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations (e.g., 3D stacked memory implementations), a dic 205 may include a host processor 210. A host processor 210 may be an example of a host system 105, or a portion thereof (e.g., a processor 125, aspects of a host system controller 120, or both). A host processor 210 may include one or more processor cores that are configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation, in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a dic 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more TSVs).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the dic 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a dic 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205-a with the die 240-a-1 may include a dielectric material 207 (e.g., an electrically non-conductive material) of the die 205-a being fused with a dielectric material 242 of the die 240-a-1, and the coupling of the dic 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube,” a memory stack, or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some implementations of a system 200, a stack of dies 240 may be bonded on top of a dic 205. However, logic circuitry of a die 205 (e.g., of interface blocks 220, of logic block(s) 225, of a logic block 230, of controller(s) 215, of a host processor 210) may be associated with relatively high-power operations and accompanying heat generation, and locating a die 205 at or near the bottom of a stack (e.g., relatively close to a system substrate or assembly surface) may result in heat rejection challenges because a thermal impedance of the dies 240 may trap heat generated by the die 205. For example, heat generated by a die 205 in such an assembly may be transferred through dies 240 to a heat sink (e.g., on top of the dies 240), resulting in relatively high temperature gradient and peak temperature (e.g., at or near the die 205). In some cases, thermal effects for heterogeneous stacks may be mitigated by placing a die 205 as an upper device for closer integration with a heat sink, which may include placing a die 205 over a stack of dies 240 in accordance with a Logic on Top (LoT) configuration. However, such a configuration may be associated with challenges for providing power to circuitry of the die 205, particularly if an integration with dies 240 increases a lateral distance (e.g., using one or more redistribution layers, around circuitry of the dies 240) over which power is conveyed to distributed circuitry of the die 205.

In accordance with examples as disclosed herein, a semiconductor system (e.g., a system 200, in a LOT configuration) may be configured with a two-dimensional pattern of power delivery conductors that pass through semiconductor components of a stack (e.g., through one or more stacks of dies 240), providing a more-distributed delivery of power to a logic component (e.g., to a die 205) bonded with the stack. The power delivery conductors may include TSVs that bypass circuitry of the stack (e.g., bypassing interface blocks 245 and memory arrays 250), and thus may be allocated to (e.g., dedicated to) providing power to the logic component. Such techniques may be combined with a redistribution component, such as a package substrate or interposer (e.g., opposite the die 205, below dies 240), which may include redistribution conductors that convert from relatively fewer interconnections (e.g., solder balls, at a relatively coarse pitch) at a surface of the semiconductor system to relatively more interconnections (e.g., fusion contacts, hybrid bonding contacts, at a relatively finer pitch) at a surface bonded with the stack that support the two-dimensional pattern of power delivery conductors. In some examples, dies 240 may be arranged in accordance with memory banks, each of which may include respective memory arrays 250 and bank logic (e.g., associated with an interface block 245) operable for accessing the respective memory arrays 250. In various implementations, a two-dimensional pattern of power delivery conductors (e.g., TSVs) may include conductors formed between the memory banks, or between the memory arrays and bank logic of one or more memory banks, or various combinations thereof. Thus, in accordance with these and other examples, power delivery may be distributed through the dies 240, thereby improving power distribution to a die 205 or other logic component in a LOT configuration by reducing a lateral distance for delivering power to distributed components of the logic component and reducing accompanying losses and power distribution complexity.

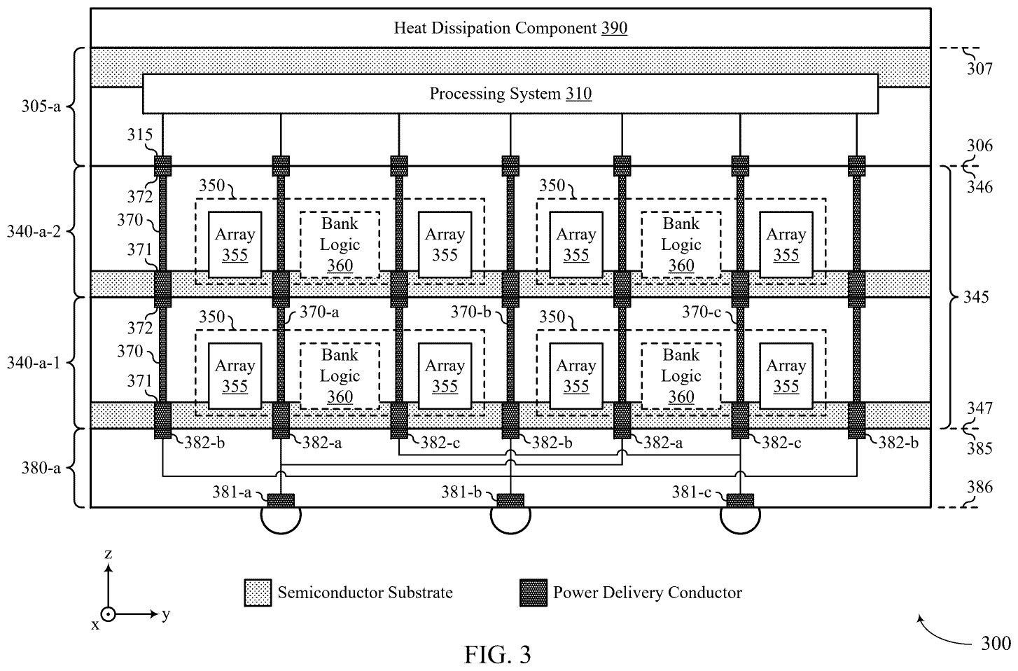

FIG. 3 shows an example of a system 300 (e.g., a semiconductor system, a system of semiconductor dies) that supports pass-through power delivery for logic-on-top semiconductor systems in accordance with examples as disclosed herein. Aspects of the system 300 may be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 300. Although FIG. 3 illustrates examples of relative dimensions and quantities of various features, aspects of a system 300 may be implemented with other relative dimensions or quantities of such features in accordance with examples as disclosed herein.

The system 300 may include a semiconductor component 305 (e.g., semiconductor component 305-a), which may be an example of aspects of a die 205. A semiconductor component 305 may include a processing system 310, which may include various implementations of processing circuitry (e.g., logic circuitry, processing units). In some examples, the processing system 310 may include one or more processors, and may be an example of aspects of a processor 125, a host processor 210, one or more controllers 215, or a combination thereof (e.g., in a 3D stacked memory implementation). For example, one or more processors of a processing system 310 may be associated with one or more processing cores, one or more GPUs, one or more CPUs, or other processing units. Additionally, or alternatively, the processing system 310 may include one or more interface blocks 220, a logic block 225, a logic block 230, or a combination thereof (e.g., in an HBM implementation). Although, in some examples, a semiconductor component 305 may be implemented as a single semiconductor die, in some other examples, a semiconductor component 305 may be implemented as multiple semiconductor dies (e.g., in a stacked arrangement, in an arrangement of chiplets, or both).

A semiconductor component 305 may include a plurality of contacts 315 that are configured to receive power (e.g., electrical power, in accordance with one or more regulated voltages relative to a ground voltage) for operating circuitry of the processing system 310. In some examples (e.g., as shown), contacts 315 may be implemented on a front side of the semiconductor component 305, where a front side may refer to a same side from which a semiconductor substrate of the semiconductor component 305 is doped to form circuitry (e.g., transistor circuitry, transistor channels, circuitry of a processing system 310). For example, as illustrated, a side 306 (e.g., a face, a surface, an interface) of the semiconductor component 305-a may correspond to a front side and a side 307 of the semiconductor component 305-a may correspond to a back side. In some examples, contacts 315 may be formed on a front side with a smaller size, a smaller pitch dimension, or both than when contacts are formed on a back side (e.g., as TSV contacts, as contacts coupled with conductors that are formed through the semiconductor substrate of the semiconductor component 305), which may support a relatively higher quantity or higher density (e.g., in an xy-plane) of contacts 315, or a relatively greater density of components (e.g., substrate components, transistors) of the processing system 310, or a combination thereof.

The system 300 may also include a set 345 of one or more semiconductor components 340 (e.g., semiconductor dies, memory dies), each of which may be an example of aspects of a die 240. The set 345 may be bonded with the semiconductor component 305-a along a side 346 of the set 345 (e.g., a side of the semiconductor component 340-a-2), which may include a fusion of conductive material of contacts 372 of vias 370 (e.g., TSVs) and contacts 315 of the semiconductor component 305-a. In some examples, such a fusion of conductive materials may be accompanied by a fusion of dielectric materials (e.g., a dielectric material 207, a dielectric material 242) at the interfacing surfaces (e.g., in accordance with a hybrid bonding implementation). Although FIG. 3 illustrates a system 300 including two semiconductor components 340 in a stack, a system 300 in accordance with the described techniques may include a single semiconductor component 340, or any quantity of multiple semiconductor components 340 (e.g., two, four, eight, twelve, sixteen, or more), which may be bonded in a stack (e.g., a memory stack). The set 345 (e.g., one or more of the semiconductor components 340) may include one or more arrays 355 (e.g., memory arrays), each of which may be an example of a memory array 155 or a memory array 250, and each of which may be accessible by at least a portion of the processing system 310 (e.g., via interface blocks 245, via interface blocks 220). In some examples, one or more of the semiconductor components 340 may include a plurality of banks 350 (e.g., memory banks), each including respective arrays 355 (e.g., a pair of arrays 355) and respective bank logic 360 (e.g., between the respective arrays 355, along an x-direction, along a y-direction, or both, including at least a portion of interface blocks 245) operable for accessing the respective arrays 355.

The set 345 (e.g., at least a bottom semiconductor component 340 of a set 345) may also include a two-dimensional array of contacts 371 (e.g., two-dimensional in an xy-plane) along a side 347 of the set 345 (e.g., of the semiconductor component 340-a-1). The contacts 371 may be coupled with the processing system 310 (e.g., via contacts 315, through one or more vias 370 along the z-direction), and may be configured to provide power for operations of the processing system 310. The contacts 371 may be coupled with the processing system 310 via respective conductive paths (e.g., vias 370) through the semiconductor components 340 that bypass circuitry for accessing the arrays 355 (e.g., bypassing the arrays 355 themselves, bypassing bank logic 360). For example, at least some of the vias 370, and respective contacts 371 and 372, may be arranged between banks 350 (e.g., along the x-direction, along the y-direction, or both), such as vias 370-a. Additionally, or alternatively, at least some of the vias 370, and respective contacts 371 and 372, may be arranged between bank logic 360 and arrays 355 of a given bank 350 (e.g., along the x-direction, along the y-direction, or both), such as via 370-b. Additionally, or alternatively, at least some vias 370 may be arranged along a periphery of one or more semiconductor components 340 (e.g., outside of banks 350), such as via 370-c.

In some examples, each of the semiconductor components 340 of a stack may include respective contacts 371, which may be aligned with one another (e.g., at least partially overlapping when viewed along the z-direction, in a same or similar pattern in an xy-plane). Additionally, or alternatively, at least some, if not all contacts 371 may be aligned with contacts 372 (e.g., of a given semiconductor component 340, through a stack of semiconductor components 340, for vias 370 passing directly between a front side and a back side of a given semiconductor component 340). In other words, a set 345, or each or one or more semiconductor components 340 of a set, may include a two-dimensional array of contacts 372 on a first surface (e.g., a side 346) and a two-dimensional array of contacts 371 arranged on a second surface (e.g., a side 347), where at least a subset of the contacts 371 are coupled with the contacts 372 through vias 370. Although the vias 370 are illustrated as having different sizes (e.g., widths, diameters, in an xy-plane, along the x-direction, along the y-direction, at different positions along the z-direction) between contacts 371 and 372, in some examples, vias 370 may be formed with a common dimension (e.g., conductor dimension) from a front side, from a back side, or both of a given semiconductor component 340 (e.g., formed in a cavity with continuous sidewalls), in which cases the contacts 371, the contacts 372, or both may refer to interfacing surfaces (e.g., contact surfaces) of the vias 370 at the front side or back side of the given semiconductor component 340.

In some examples, a first set of contacts 371 (e.g., a first set of TSVs, a first set of contacts 372, a first set of contacts 315, including at least a contact 371 associated with via 370-a) may be associated with a supply voltage (e.g., a positive supply voltage, Voltage Drain Drain (Vdd)), and a second set of contacts 371 (e.g., including at least a contact 371 associated with via 370-b) may be associated with a ground voltage (e.g., GND, Voltage Source Source (Vss)). In some examples, one or more other sets of TSVs (e.g., including at least a contact 371 associated with via 370-c) may be associated with another supply voltage (e.g., another positive supply voltage, a negative supply voltage, an emitter voltage (Vee), a collector voltage (Vcc)), which may be associated with a different voltage level for supplying power to the processing system 310, or a different voltage regulation characteristic (e.g., a different filtering characteristic, a different jitter characteristic, a different regulation stability, a different switching characteristic), or a combination thereof than the first set of contacts 371. Although the illustration of FIG. 3 provides an example of such techniques for two different voltages, different contacts 371 associated with different voltages may be distributed differently, or may be implemented with different quantities or ratios of contacts 371, or with any quantity of one or more supply voltages, among other configurations.

In some examples, power may be distributed from a relatively smaller quantity of contacts at a package interface to a relatively greater quantity of contacts at an interface with a set 345 (e.g., through a set 345). Such techniques may support a finer granularity of power distribution through the set 345 and area of a semiconductor component 305, and may leverage relatively finer granularity semiconductor component bonding techniques (e.g., hybrid bonding) than package assembly techniques (e.g., solder bonding). For example, as shown, a system 300 may also include a semiconductor component 380 (e.g., semiconductor component 380-a, an interposer, a system substrate) that is bonded with the set 345 along the side 347 of the set 345. The semiconductor component 380-a may include a two-dimensional array of contacts 382 along a side 385 of the semiconductor component 380 that are coupled with the contacts 371 along the side 347 of the set 345. The semiconductor component 380-a also includes a plurality of contacts 381 along a side 386 of the semiconductor component 380-a that are coupled with the contacts 382 (e.g., via one or more redistribution layers, via one or more power planes, via relatively thick conductor configurations to reduce distribution losses), for which there are fewer contacts 381 than contacts 382. For example, a contact 381-a may be associated with a first supply voltage, a contact 381-b may be associated with a ground voltage, and a contact 381-c may be associated with a second supply voltage having different characteristics than the first supply voltage. In some such examples, a single contact 381 may be coupled with multiple contacts 382 (e.g., contact 381-a coupled with contacts 382-a, contact 381-b coupled with contacts 382-b, contact 381-c coupled with contacts 382-c), such as tens of contacts 382, hundreds of contacts 382, thousands of contacts 382, or tens of thousands of contacts 382, and so on. Accordingly, the contacts 382 may be associated with a first pitch dimension (e.g., along the x-direction, along the y-direction, or both), and the contacts 381 may be associated with a second pitch dimension that is greater than the first pitch dimension, which may facilitate relatively larger interconnections at an interface of the system 300 (e.g., on the side 386 of the semiconductor component 380), such as solder ball connections (e.g., compared to fusion bonding of contacts 382 with contacts 371). Although the illustration shows a single contact 381 being allocated to a respective supply voltage, the described techniques may be supported by any quantity of one or more contacts 381 being allocated to a given supply voltage, which may be implemented for any quantity of one or more supply voltages.

In some examples, the bonding of the set 345 with the semiconductor component 305-a may be performed in accordance with a front-to-front bonding (e.g., bonding a front side of the semiconductor component 340-a-2 with a front side of the semiconductor component 305-a. For example, semiconductor components 340 may be formed with relatively fine-pitch vias 370, but manufacturing processes or designs for a semiconductor component 305 may not support such fine-pitch TSVs. Accordingly, by bonding with a front side of the semiconductor component 305-a and, in some examples, a front side of the semiconductor component 340-a-2, interconnections may be supported with a relatively fine pitch without implementing fine-pitch TSVs (e.g., vias that pass through a semiconductor substrate of the semiconductor component 305-a) at the semiconductor component 305-a. Additionally, or alternatively, bonding with a front side of a semiconductor component 340-a-2 may support various redistribution techniques in a metallization layer of the semiconductor component 340-a-2, such as techniques in which a quantity, size, or distribution of contacts 372 along the side 346 may be different from an quantity, size, or distribution of contacts 371 (e.g., on a side 347, on a side of a set 345 or of a semiconductor component 340 opposite the side 346).

The system 300 may also include a heat dissipation component 390 bonded with the semiconductor component 305-a, such that the semiconductor component 305-a is between the heat dissipation component 390 and the set 345. The heat dissipation component 390 may include various implementations, such as a cold plate, a heat sink, a liquid cooling heat exchanger, a thermoelectric cooler, or other component that draws heat from the system 300. By locating the heat dissipation component 390 relatively close to the processing system 310, heat from the operations of the processing system 310 may be dissipated relatively efficiently, compared with configurations in which such heat is dissipated through semiconductor components 340, among other implementations.

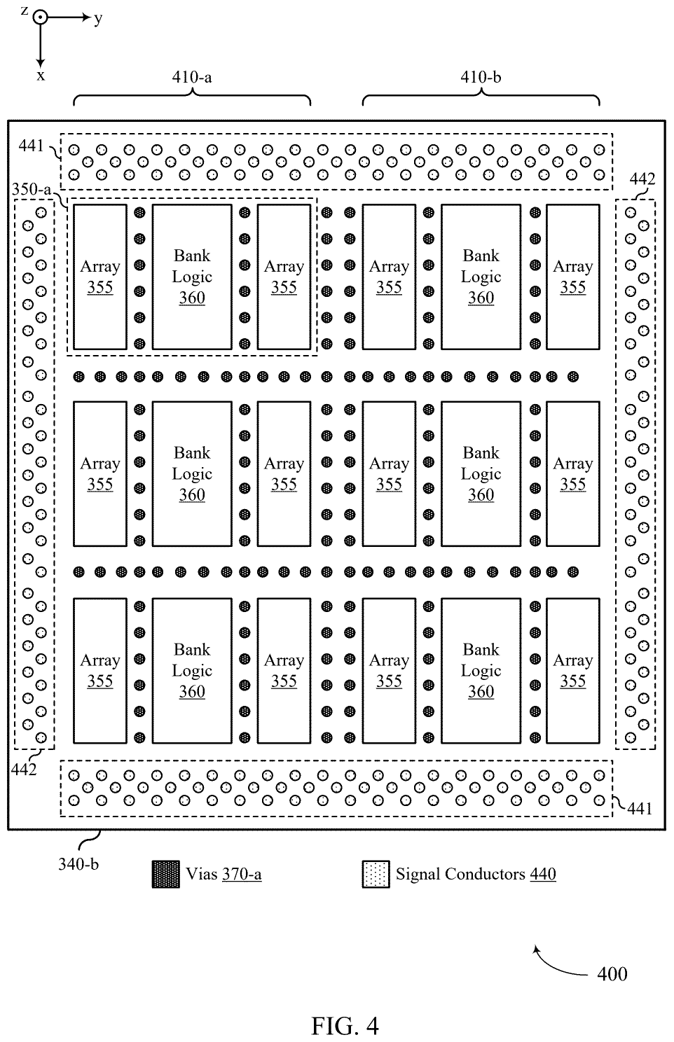

FIG. 4 shows an example of a layout 400 that supports pass-through power delivery for logic-on-top semiconductor systems in accordance with examples as disclosed herein. The layout 400 may represent a top-down view (e.g., a cross-section in an xy-plane) of one or more semiconductor components 340 (e.g., semiconductor component 340-b). A layout 400 may include a plurality of banks 350-a, each including a respective set of arrays 355 and bank logic 360. In the example of layout 400, banks 350-a may be arranged in accordance with channels 410 (e.g., a channel 410-a including a first set of banks 350-a, a channel 410-b including a second set of banks 350-a). In some examples, each channel 410 may correspond to an independently-accessible portion of memory that supports parallel processing of data delivered with a processing system 310, and may correspond to a respective logic block 225, a respective host interface 216, or a respective controller 215, among other implementations.

The layout 400 illustrates an example of a two-dimensional array of vias 370-a, which may support power delivery to a processing system 310 of a semiconductor component 305 coupled with the semiconductor component 340-b. For example, vias 370-a may be arranged between banks 350-a, between channels 410, between bank logic 360 and adjacent (e.g., associated, coupled) arrays 355 (e.g., along TSV corridors), among other examples. Each of the vias 370-a may be associated with a respective contact 371 and a respective contact 372, which may support coupling with contacts of semiconductor components 305 or 340 adjacent to the semiconductor component 340-b. In some examples (e.g., as illustrated), vias 370-a may be associated with a circular cross-section (e.g., in an xy-plane), which may facilitate component or processing uniformity. However, in some other examples, vias 370 may be formed with other cross-sectional shapes, such as square, rectangular, polygonal, elliptical, or other shapes.

The layout 400 also illustrates an implementation of signal conductors 440, which may represent vias (e.g., TSVs) through the semiconductor component 340-b (e.g., through one or more bypass regions, through one or more semiconductor extensions not occupied by operational circuitry of the semiconductor component 340-b). For example, signal conductors 440 in one or more regions 441 may be associated with signaling between one or more semiconductor components 340 and a semiconductor component 305 (e.g., a processing system 310), which may include a conductive path of a bus 246 or a bus 255. In another example, signal conductors 440 in one or more regions 442 may be associated with signaling between a semiconductor component 305 (e.g., a processing system 310) and a semiconductor component 380 (e.g., a package substrate, an interposer). In some examples, regions 441 may include a larger quantity of signal conductors 440 than regions 442 (e.g., for greater throughput), or signal conductors 440 with a finer pitch than regions 442 (e.g., for more relaxed bonding requirements between a set 345 and a semiconductor component 380), or both. However, signal conductors 440 may be implemented in accordance with other arrangements, distributions, or for carrying signals among other components of a system 300. In some examples, signal conductors 440 may be implemented for carrying signals to or from circuitry of the semiconductor component 340-b. Additionally, or alternatively, signal conductors 440 may be implemented for carrying signals through the semiconductor component 340-b (e.g., bypassing circuitry of the semiconductor component 340-b). In some examples, vias 370-a may also be implemented in regions 441 or 442, among other locations of the layout 400.

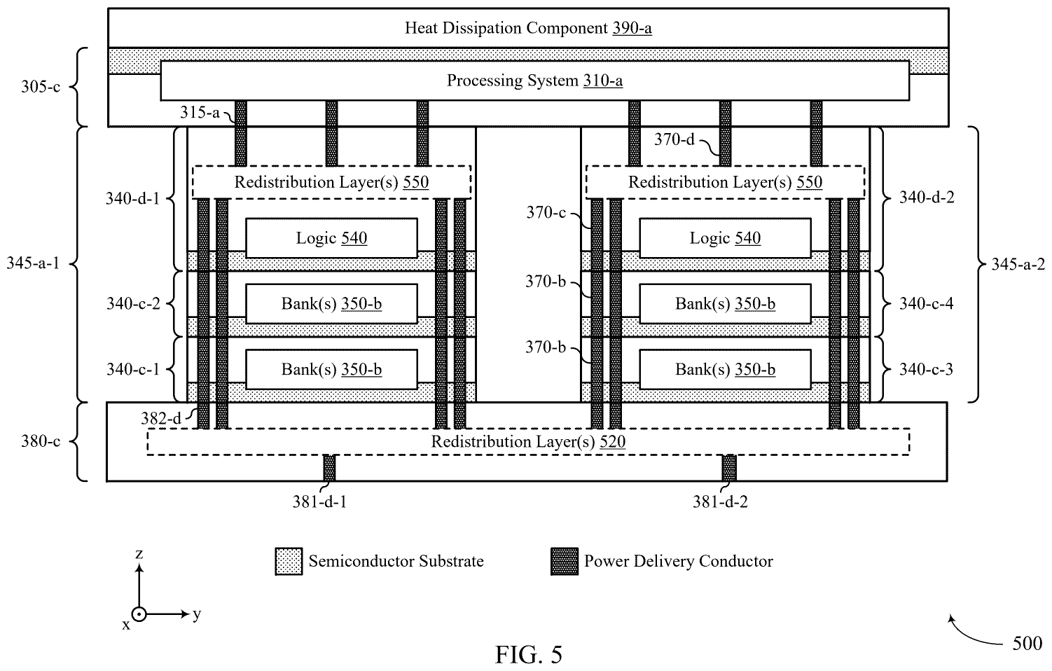

FIG. 5 shows an example of a system 500 (e.g., a semiconductor system, a system of semiconductor dies) that supports pass-through power delivery for logic-on-top semiconductor systems in accordance with examples as disclosed herein. Aspects of the system 500 may be described with reference to an x-direction, a y-direction, and a z-direction of the illustrated coordinate system, where the z-direction may be illustrative of a direction (e.g., a vertical direction, a thickness direction, a stack direction) that is orthogonal to or otherwise relative to a surface in an xy-plane (e.g., a substrate plane, a coupling plane) of the system 500. Although FIG. 5 illustrates examples of relative dimensions and quantities of various features, aspects of a system 500 may be implemented with other relative dimensions or quantities of such features in accordance with examples as disclosed herein.

The system 500 may include a semiconductor component 305-c, which may include a processing system 310-a. The processing system 310 may include one or more processors, and may be an example of aspects of a processor 125, a host processor 210, one or more controllers 215, or a combination thereof. The semiconductor component 305-c may include a plurality of contacts 315-a that are configured to receive power for operating circuitry of the processing system 310-a. The system 300 may also include a heat dissipation component 390-a, which may be bonded with the semiconductor component 305-c.

The system 300 may also include multiple sets 345-a (e.g., sets 345-a-1 and 345-a-2) of semiconductor components 340. For example, each set 345-a may include a respective set of one or more semiconductor components 340-c, each of which may be an example of aspects of a die 240. Each semiconductor component 340-c may include a respective set of one or more banks 350-b, among other components. Although FIG. 5 illustrates sets 345-a including two semiconductor components 340-c in a stack, a set 345-a in accordance with the described techniques may include a single semiconductor component 340-c, or any quantity of multiple semiconductor components 340-c (e.g., two, four, eight, twelve, sixteen, or more), which may be bonded in a stack (e.g., a memory stack).

Each set 345-a may also include a respective semiconductor component 340-d, which may be an example of aspects of a die 205. For example, each of the semiconductor components 340-d may include logic 540, which may refer to aspects of interface blocks 220, one or more logic blocks 225, one or more controllers 215 (e.g., when not included in the semiconductor component 305-c), various implementations of data sense amplification (e.g., to support relatively low-level signaling between the logic 540 and banks 350-b, such as signaling in accordance with a memory cell sense amplification voltage), or a combination thereof. In some examples, a semiconductor component 340-d may be referred to as a data proximity layer (DPL), and logic 540 of such a semiconductor component 340-d may facilitate operations between the processing system 310-a and the banks 350-b with circuitry separate from semiconductor components 340-c and 305-c.

Each set 345-a may be bonded with the semiconductor component 305-c along a first side of the set 345-a (e.g., a side 346), which may include a fusion of conductive material of vias 370-d (e.g., contacts 372, contacts 212) and contacts 315-a. In some examples, such a fusion of conductive materials may be accompanied by a fusion of dielectric materials at the interfacing surfaces (e.g., in accordance with a hybrid bonding implementation). Each set 345-a (e.g., at least a bottom semiconductor component 340-c of a set 345-c) may also include a two-dimensional array of vias 370-b, and associated contacts 371, along a second side (e.g., a side 347) of the set 345-a (e.g., of a semiconductor component 340-c). A system 500 may also include one or more semiconductor components 380-c that are bonded with one or more of the sets 345-a (e.g., both sets 345-a-1 and 345-a-2, as illustrated). The semiconductor component 380-c may include a two-dimensional array of contacts 382-d that are bonded with contacts 371 of the vias 370-b (e.g., of semiconductor components 340-c-1 and 340-c-3). The semiconductor component 380-c may also include contacts 381-d that are coupled with the contacts 382-d via redistribution layer(s) 520. The redistribution layer(s) 520 may support a coupling of contacts 382-d with a relatively smaller quantity of contacts 381-d, which may facilitate relatively larger interconnections at an interface of the system 500 (e.g., a package interface, in accordance with a package pitch). In some implementations, redistribution layer(s) 520 may include or be connected with decoupling capacitors, which may improve uniformity (e.g., reduce noise, reduce jitter) of power provided through the contacts 382-d.

In some implementations, semiconductor components 340-d may also include redistribution layer(s) 550, which may convert between a first quantity of vias 370-c (e.g., a first quantity of vias 370-b, a first quantity of contacts 371) and a second quantity of vias 370-d (e.g., a second quantity of contacts 372). For example, vias 370-b and 370-c may be formed and bonded in accordance with a first manufacturing technology, which may support relatively fine-pitch TSVs and hybrid bonding techniques. By implementing vias 370-d with a relatively lower quantity (e.g., than vias 370-b and 370-c), an interface between sets 345-a and a semiconductor component 305-c may be provided with relatively relaxed tolerances, or relatively larger interconnections, or both, which may facilitate integration of sets 345-a with semiconductor components 305-c. In some examples, redistribution layer(s) 550 may be configured for (e.g., modified for) semiconductor components 305-c of different designs, which may provide flexibility for implementing standardized semiconductor components 340-c with different designs of semiconductor components 305-c.

In some examples, the bonding of the sets 345-a with the semiconductor component 305-c may also be performed in accordance with a front-to-front bonding (e.g., bonding a front side of semiconductor components 340-d-1 and 340-d-2 with a front side of the semiconductor component 305-c). By bonding with a front side of the semiconductor component 305-c and, in some examples, a front side of the semiconductor components 340-d, interconnections may be supported with a relatively fine pitch without implementing fine-pitch TSVs (e.g., vias that pass through a semiconductor substrate of the semiconductor component 305-c) at the semiconductor component 305-c.

Thus, in accordance with these and other examples, a semiconductor system (e.g., a system 300, a system 500, among other configurations) may be provided with a two-dimensional pattern of power delivery conductors (e.g., vias 370) that pass through semiconductor components 340 of a set 345, providing a more-distributed delivery of power to a logic component (e.g., a semiconductor component 305, a processing system 310) bonded with the set 345. The vias 370 may bypass circuitry of the stack (e.g., bypassing banks 350, among other circuitry), and thus may be allocated for providing power to the logic component. Such techniques may be combined with a redistribution component (e.g., a semiconductor component 380, redistribution layer(s) 520, redistribution layer(s) 550) to convert between relatively fewer interconnections and relatively more interconnections at various layers or interfaces of the semiconductor system. Thus, in accordance with these and other examples, power delivery may be distributed through semiconductor components 340, thereby improving power distribution in a LOT configuration by reducing a lateral distance for delivering power to distributed components of a logic component and reducing accompanying losses and distribution complexity.

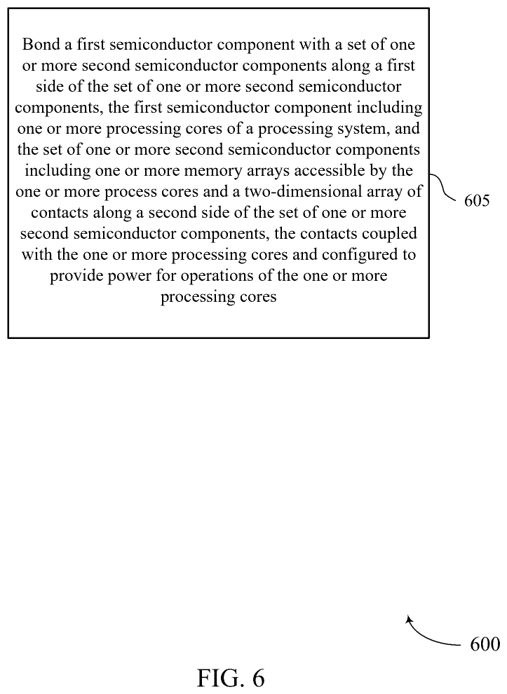

FIG. 6 shows a flowchart illustrating a method 600 that supports pass-through power delivery for logic-on-top semiconductor systems in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include bonding a first semiconductor component (e.g., a semiconductor component 305) with a set (e.g., a set 345) of one or more second semiconductor components (e.g., semiconductor component(s) 340) along a first side of the set of one or more second semiconductor components. The first semiconductor component may include one or more processors of a processing system (e.g., a processing system 310), and the set of one or more second semiconductor components may include one or more memory arrays (e.g., arrays 355) accessible by the one or more processors and a two-dimensional array of contacts (e.g., contacts 371) along a second side of the set of one or more second semiconductor components, the contacts coupled with the one or more processors and configured to provide power for operations of the one or more processors.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method, apparatus, or non-transitory computer-readable medium including operations, features, circuitry, logic, means, or instructions, or any combination thereof for bonding a first semiconductor component (e.g., a semiconductor component 305) with a set (e.g., a set 345) of one or more second semiconductor components (e.g., semiconductor component(s) 340) along a first side (e.g., a side 346) of the set of one or more second semiconductor components. In some examples, the first semiconductor component may include one or more processors of a processing system (e.g., a processing system 310), and the set of one or more second semiconductor components may include one or more memory arrays (e.g., arrays 355) accessible by the one or more processors and a two-dimensional array of contacts (e.g., contacts 371) along a second side (e.g., a side 347) of the set of one or more second semiconductor components, the contacts coupled with the one or more processors and configured to provide power for operations of the one or more processors.

Aspect 2: The method, apparatus, or non-transitory computer-readable medium of aspect 1, where the two-dimensional array of contacts are coupled with the one or more processors via respective conductive paths through the set of one or more second semiconductor components that bypass circuitry for accessing the one or more memory arrays.

Aspect 3: The method, apparatus, or non-transitory computer-readable medium of any of aspects 1 through 2, where the set of one or more second semiconductor components includes a plurality of semiconductor dies in a stack, each of the plurality of semiconductor dies including a plurality of memory banks including respective memory arrays of the one or more memory arrays and a plurality of through-substrate vias arranged between the plurality of memory banks, where at least a subset of the two-dimensional array of contacts are coupled with the one or more processors using the plurality of through-substrate vias of the plurality of semiconductor dies in the stack.

Aspect 4: The method, apparatus, or non-transitory computer-readable medium of aspect 3, where each of the plurality of semiconductor dies further includes a plurality of second through-substrate vias arranged between respective bank logic of the plurality of memory banks and the respective memory arrays of the plurality of memory banks, where at least a second subset of the two-dimensional array of contacts are coupled with the one or more processors using the plurality of second through-substrate vias of the plurality of semiconductor dies in the stack.

Aspect 5: The method, apparatus, or non-transitory computer-readable medium of any of aspects 1 through 4, where the two-dimensional array of contacts includes a first plurality of contacts associated with a supply voltage and a second plurality of contacts associated with a ground voltage.

Aspect 6: The method, apparatus, or non-transitory computer-readable medium of aspect 5, where the two-dimensional array of contacts includes a third plurality of contacts associated with a second supply voltage.

Aspect 7: The method, apparatus, or non-transitory computer-readable medium of aspect 6, where the supply voltage is associated with a first voltage level and the second supply voltage is associated with a second voltage level different from the first voltage level.

Aspect 8: The method, apparatus, or non-transitory computer-readable medium of any of aspects 6 through 7, where the supply voltage is associated with a first voltage regulation characteristic and the second supply voltage is associated with a second voltage regulation characteristic different from the first voltage regulation characteristic.

Aspect 9: The method, apparatus, or non-transitory computer-readable medium of any of aspects 1 through 8, further including operations, features, circuitry, logic, means, or instructions, or any combination thereof for bonding a third semiconductor component with the set of one or more second semiconductor components along the second side of the set of one or more second semiconductor components, the third semiconductor component including a two-dimensional array of second contacts along a first side of the third semiconductor component that are coupled with the two-dimensional array of contacts along the second side of the set of one or more second semiconductor components, and a plurality of third contacts along a second side of the third semiconductor component that are coupled with the two-dimensional array of second contacts, a quantity of the plurality of third contacts being less than a quantity of the two-dimensional array of second contacts.

Aspect 10: The method, apparatus, or non-transitory computer-readable medium of aspect 9, where the two-dimensional array of second contacts is associated with a first pitch dimension and the plurality of third contacts is associated with a second pitch dimension that is greater than the first pitch dimension.

Aspect 11: The method, apparatus, or non-transitory computer-readable medium of any of aspects 9 through 10, where bonding the first semiconductor component with the set of one or more second semiconductor components includes bonding a front side of one of the set of one or more second semiconductor components with a front side of the first semiconductor component.

Aspect 12: The method, apparatus, or non-transitory computer-readable medium of any of aspects 1 through 11, where bonding the first semiconductor component with the set of one or more second semiconductor components includes fusing dielectric material portions and fusing conductive material portions.

Aspect 13: The method, apparatus, or non-transitory computer-readable medium of any of aspects 1 through 12, further including operations, features, circuitry, logic, means, or instructions, or any combination thereof for bonding a heat dissipation component with the first semiconductor component such that the first semiconductor component is between the heat dissipation component and the set of one or more second semiconductor components.

Aspect 14: The method, apparatus, or non-transitory computer-readable medium of any of aspects 1 through 13, where the one or more processors are associated with one or more graphics processing units (GPUs).

Aspect 15: The method, apparatus, or non-transitory computer-readable medium of any of aspects 1 through 14, further including operations, features, circuitry, logic, means, or instructions, or any combination thereof for bonding a set of one or more fourth semiconductor components with the first semiconductor component along a first side of the set of one or more fourth semiconductor components, the set of one or more fourth semiconductor components including one or more second memory arrays accessible by the one or more processors and a two-dimensional array of second contacts along a second side of the set of one or more fourth semiconductor components, the second contacts coupled with the one or more processors and configured to provide power for operations of the one or more processors.

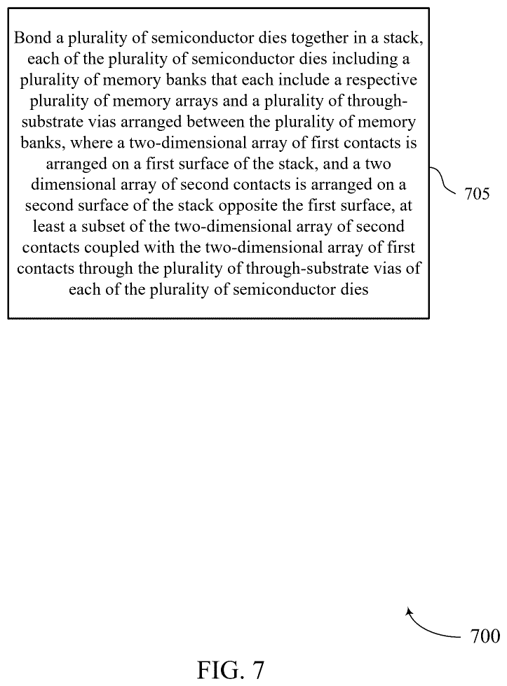

FIG. 7 shows a flowchart illustrating a method 700 that supports pass-through power delivery for logic-on-top semiconductor systems in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include bonding a plurality of semiconductor dies (e.g., semiconductor components 340) together in a stack (e.g., a set 345), each of the plurality of semiconductor dies including a plurality of memory banks (e.g., banks 350) each including a respective plurality of memory arrays (e.g., arrays 355), and a plurality of through-substrate vias (e.g., vias 370) arranged between the plurality of memory banks. In some examples, a two-dimensional array of first contacts (e.g., contacts 372) is arranged on a first surface of the stack (e.g., of a side 346), and a two dimensional array of second contacts (e.g., contacts 371) arranged on a second surface of the stack opposite the first surface (e.g., of a side 347), at least a subset of the two-dimensional array of second contacts coupled with the two-dimensional array of first contacts through the plurality of through-substrate vias of each of the plurality of semiconductor dies.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 16: A method, apparatus, or non-transitory computer-readable medium including operations, features, circuitry, logic, means, or instructions, or any combination thereof for bonding a plurality of semiconductor dies (e.g., semiconductor components 340) together in a stack (e.g., a set 345), each of the plurality of semiconductor dies including a plurality of memory banks (e.g., banks 350) each including a respective plurality of memory arrays (e.g., arrays 355), and a plurality of through-substrate vias (e.g., vias 370) arranged between the plurality of memory banks. In some examples, a two-dimensional array of first contacts (e.g., contacts 372) is arranged on a first surface of the stack (e.g., of a side 346), and a two dimensional array of second contacts (e.g., contacts 371) arranged on a second surface of the stack opposite the first surface (e.g., of a side 347), at least a subset of the two-dimensional array of second contacts coupled with the two-dimensional array of first contacts through the plurality of through-substrate vias of each of the plurality of semiconductor dies.

Aspect 17: The method, apparatus, or non-transitory computer-readable medium of aspect 16, where a quantity of the two-dimensional array of first contacts is different from a quantity of the two-dimensional array of second contacts.

Aspect 18: The method, apparatus, or non-transitory computer-readable medium of any of aspects 16 through 17, where each of the plurality of semiconductor dies further includes a plurality of second through-substrate vias arranged between respective bank logic of the plurality of memory banks and the respective plurality of memory arrays of the plurality of memory banks, where at least a second subset of the two-dimensional array of second contacts is coupled with the two-dimensional array of first contacts through the plurality of second through-substrate vias of each of the plurality of semiconductor dies.

Aspect 19: The method, apparatus, or non-transitory computer-readable medium of any of aspects 16 through 18, where the two-dimensional array of first contacts are aligned with the two-dimensional array of second contacts through the stack.

Aspect 20: The method, apparatus, or non-transitory computer-readable medium of any of aspects 16 through 19, further including operations, features, circuitry, logic, means, or instructions, or any combination thereof for bonding a third semiconductor component with the stack, the third semiconductor component including: a two-dimensional array of third contacts along a first side of the third semiconductor component that are coupled with the two-dimensional array of second contacts and a plurality of fourth contacts along a second side of the third semiconductor component that are coupled with the two-dimensional array of second contacts, a quantity of the plurality of fourth contacts being less than a quantity of the two-dimensional array of second contacts.

Aspect 21: The method, apparatus, or non-transitory computer-readable medium of aspect 20, where the two-dimensional array of second contacts is associated with a first pitch dimension and the plurality of fourth contacts is associated with a second pitch dimension that is greater than the first pitch dimension.

Aspect 22: The method, apparatus, or non-transitory computer-readable medium of any of aspects 16 through 21, where bonding the plurality of semiconductor dies in the stack includes fusing dielectric material portions and fusing conductive material portions.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 23: A semiconductor system (e.g., a system 300, a system 500, or portion thereof), including: a first semiconductor component (e.g., a semiconductor component 305) including one or more processors of a processing system (e.g., a processing system 310); and one or more second semiconductor components (e.g., semiconductor component(s) 340) bonded with the first semiconductor component along a first side (e.g., a side 346) of the one or more second semiconductor components, the one or more second semiconductor components including: one or more memory arrays (e.g., array(s) 355) accessible by the one or more processors; and a two-dimensional array of contacts (e.g., contacts 371) along a second side (e.g., a side 347) of the one or more second semiconductor components, the contacts coupled with the one or more processors and configured to provide power for operations of the one or more processors.

Aspect 24: The semiconductor system of aspect 23, where the two-dimensional array of contacts are coupled with the one or more processors via respective conductive paths through the one or more second semiconductor components that bypass circuitry for accessing the one or more memory arrays.

Aspect 25: The semiconductor system of any of aspects 23 through 24, where the one or more second semiconductor components include a plurality of semiconductor dies in a stack, each of the plurality of semiconductor dies including: a plurality of memory banks including respective memory arrays of the one or more memory arrays; and a plurality of through-substrate vias arranged between the plurality of memory banks, where at least a subset of the two-dimensional array of contacts are coupled with the one or more processors using the plurality of through-substrate vias of the plurality of semiconductor dies in the stack.

Aspect 26: The semiconductor system of aspect 25, where each of the plurality of semiconductor dies further includes: a plurality of second through-substrate vias arranged between respective bank logic of the plurality of memory banks and the respective memory arrays of the plurality of memory banks, where at least a second subset of the two-dimensional array of contacts are coupled with the one or more processors using the plurality of second through-substrate vias of the plurality of semiconductor dies in the stack.

Aspect 27: The semiconductor system of any of aspects 23 through 26, where the two-dimensional array of contacts includes: a first plurality of contacts associated with a supply voltage; and a second plurality of contacts associated with a ground voltage.

Aspect 28: The semiconductor system of aspect 27, where the two-dimensional array of contacts includes: a third plurality of contacts associated with a second supply voltage.

Aspect 29: The semiconductor system of aspect 28, where: the supply voltage is associated with a first voltage level; and the second supply voltage is associated with a second voltage level different from the first voltage level.

Aspect 30: The semiconductor system of any of aspects 28 through 29, where: the supply voltage is associated with a first voltage regulation characteristic; and the second supply voltage is associated with a second voltage regulation characteristic different from the first voltage regulation characteristic.

Aspect 31: The semiconductor system of any of aspects 23 through 30, further including: a third semiconductor component bonded with the one or more second semiconductor components along the second side of the one or more second semiconductor components, the third semiconductor component including: a two-dimensional array of second contacts along a first side of the third semiconductor component that are coupled with the two-dimensional array of contacts along the second side of the one or more second semiconductor components; and a plurality of third contacts along a second side of the third semiconductor component that are coupled with the two-dimensional array of second contacts, a quantity of the plurality of third contacts being less than a quantity of the two-dimensional array of second contacts.

Aspect 32: The semiconductor system of aspect 31, where: the two-dimensional array of second contacts is associated with a first pitch dimension; and the plurality of third contacts is associated with a second pitch dimension that is greater than the first pitch dimension.

Aspect 33: The semiconductor system of any of aspects 23 through 32, where the bonding of the one or more second semiconductor components with the first semiconductor component is associated with a bonding of a front side of one of the one or more second semiconductor components with a front side of the first semiconductor component.

Aspect 34: The semiconductor system of any of aspects 23 through 33, where the one or more processors are associated with one or more graphics processing units (GPUs).

Aspect 35: The semiconductor system of any of aspects 23 through 34, further comprising: one or more fourth semiconductor components bonded with the first semiconductor component along a first side of the one or more fourth semiconductor components, the one or more fourth semiconductor components including: one or more second memory arrays accessible by the one or more processors; and a two-dimensional array of second contacts along a second side of the one or more fourth semiconductor components, the second contacts coupled with the one or more processors and configured to provide power for operations of the one or more processors.

Aspect 36: The semiconductor system of any of aspects 23 through 35, where the bonding of the one or more second semiconductor components with the first semiconductor component includes a fusion of dielectric material portions and a fusion of conductive material portions.

Aspect 37: The semiconductor system of any of aspects 23 through 36, further including: a heat dissipation component bonded with the first semiconductor component such that the first semiconductor component is between the heat dissipation component and the one or more second semiconductor components.

An apparatus is described. The following provides an overview of aspects of the apparatus as described herein:

Aspect 38: A semiconductor system (e.g., a system 300, a system 500, or portion thereof), including: a plurality of semiconductor dies (e.g., semiconductor components 340) bonded together in a stack (e.g., a set 345), each of the plurality of semiconductor dies including: a plurality of memory banks (e.g., banks 350) each including a respective plurality of memory arrays (e.g., arrays 355); and a plurality of through-substrate vias (e.g., vias 370) arranged between the plurality of memory banks; a two-dimensional array of first contacts (e.g., contacts 372) arranged on a first surface of the stack (e.g., of a side 346); and a two dimensional array of second contacts (e.g., contacts 371) arranged on a second surface of the stack (e.g., of a side 347) opposite the first surface, at least a subset of the two-dimensional array of second contacts coupled with the two-dimensional array of first contacts through the plurality of through-substrate vias of each of the plurality of semiconductor dies.

Aspect 39: The semiconductor system of aspect 38, where a quantity of the two-dimensional array of first contacts is different from a quantity of the two-dimensional array of second contacts.

Aspect 40: The semiconductor system of any of aspects 38 through 39, where each of the plurality of semiconductor dies further includes: a plurality of second through-substrate vias arranged between respective bank logic of the plurality of memory banks and the respective plurality of memory arrays of the plurality of memory banks, where at least a second subset of the two-dimensional array of second contacts is coupled with the two-dimensional array of first contacts through the plurality of second through-substrate vias of each of the plurality of semiconductor dies.

Aspect 41: The semiconductor system of any of aspects 38 through 40, where the two-dimensional array of first contacts are aligned with the two-dimensional array of second contacts through the stack.

Aspect 42: The semiconductor system of any of aspects 38 through 41, further including: a third semiconductor component bonded with the stack, the third semiconductor component including: a two-dimensional array of third contacts along a first side of the third semiconductor component that are coupled with the two-dimensional array of second contacts; and a plurality of fourth contacts along a second side of the third semiconductor component that are coupled with the two-dimensional array of second contacts, a quantity of the plurality of fourth contacts being less than a quantity of the two-dimensional array of second contacts.

Aspect 43: The semiconductor system of aspect 42, where: the two-dimensional array of second contacts is associated with a first pitch dimension; and the plurality of fourth contacts is associated with a second pitch dimension that is greater than the first pitch dimension.

Aspect 44: The semiconductor system of any of aspects 38 through 43, where the bonding between the plurality of semiconductor dies includes a fusion of dielectric material portions and a fusion of conductive material portions.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor system, comprising:
a first semiconductor component comprising one or more processors of a processing system; and
one or more second semiconductor components bonded with the first semiconductor component along a first side of the one or more second semiconductor components, the one or more second semiconductor components comprising:
one or more memory arrays accessible by the one or more processors; and
a two-dimensional array of contacts along a second side of the one or more second semiconductor components, the contacts coupled with the one or more processors and configured to provide power for operations of the one or more processors.

2. The semiconductor system of claim 1, wherein the two-dimensional array of contacts are coupled with the one or more processors via respective conductive paths through the one or more second semiconductor components that bypass circuitry for accessing the one or more memory arrays.

3. The semiconductor system of claim 1, wherein the one or more second semiconductor components comprises a plurality of semiconductor dies in a stack, each of the plurality of semiconductor dies comprising:
a plurality of memory banks comprising respective memory arrays of the one or more memory arrays; and
a plurality of through-substrate vias arranged between the plurality of memory banks,
wherein at least a subset of the two-dimensional array of contacts are coupled with the one or more processors using the plurality of through-substrate vias of the plurality of semiconductor dies in the stack.

4. The semiconductor system of claim 3, wherein each of the plurality of semiconductor dies further comprises:
a plurality of second through-substrate vias arranged between respective bank logic of the plurality of memory banks and the respective memory arrays of the plurality of memory banks,
wherein at least a second subset of the two-dimensional array of contacts are coupled with the one or more processors using the plurality of second through-substrate vias of the plurality of semiconductor dies in the stack.

5. The semiconductor system of claim 1, wherein the two-dimensional array of contacts comprises:
a first plurality of contacts associated with a supply voltage; and
a second plurality of contacts associated with a ground voltage.

6. The semiconductor system of claim 5, wherein the two-dimensional array of contacts comprises:
a third plurality of contacts associated with a second supply voltage.

7. The semiconductor system of claim 6, wherein:
the supply voltage is associated with a first voltage level; and
the second supply voltage is associated with a second voltage level different from the first voltage level.

8. The semiconductor system of claim 6, wherein:
the supply voltage is associated with a first voltage regulation characteristic; and
the second supply voltage is associated with a second voltage regulation characteristic different from the first voltage regulation characteristic.

9. The semiconductor system of claim 1, further comprising:
a third semiconductor component bonded with the one or more second semiconductor components along the second side of the one or more second semiconductor components, the third semiconductor component comprising:
a two-dimensional array of second contacts along a first side of the third semiconductor component that are coupled with the two-dimensional array of contacts along the second side of the one or more second semiconductor components; and
a plurality of third contacts along a second side of the third semiconductor component that are coupled with the two-dimensional array of second contacts, a quantity of the plurality of third contacts being less than a quantity of the two-dimensional array of second contacts.

10. The semiconductor system of claim 9, wherein:
the two-dimensional array of second contacts is associated with a first pitch dimension; and
the plurality of third contacts is associated with a second pitch dimension that is greater than the first pitch dimension.

11. The semiconductor system of claim 1, wherein the bonding of the one or more second semiconductor components with the first semiconductor component is associated with a bonding of a front side of one of the one or more second semiconductor components with a front side of the first semiconductor component.

12. The semiconductor system of claim 1, wherein the one or more processors are associated with one or more graphics processing units (GPUs).

13. The semiconductor system of claim 1, further comprising:
one or more fourth semiconductor components bonded with the first semiconductor component along a first side of the one or more fourth semiconductor components, the one or more fourth semiconductor components comprising:
one or more second memory arrays accessible by the one or more processors; and
a two-dimensional array of second contacts along a second side of the one or more fourth semiconductor components, the second contacts coupled with the one or more processors and configured to provide power for operations of the one or more processors.

14. The semiconductor system of claim 1, wherein the bonding of the one or more second semiconductor components with the first semiconductor component comprises a fusion of dielectric material portions and a fusion of conductive material portions.

15. The semiconductor system of claim 1, further comprising:
a heat dissipation component bonded with the first semiconductor component such that the first semiconductor component is between the heat dissipation component and the one or more second semiconductor components.

16. A semiconductor system, comprising:
a plurality of semiconductor dies bonded together in a stack, each of the plurality of semiconductor dies comprising:
a plurality of memory banks each comprising a respective plurality of memory arrays; and
a plurality of through-substrate vias arranged between the plurality of memory banks;
a two-dimensional array of first contacts arranged on a first surface of the stack; and
a two dimensional array of second contacts arranged on a second surface of the stack opposite the first surface, at least a subset of the two-dimensional array of second contacts coupled with the two-dimensional array of first contacts through the plurality of through-substrate vias of each of the plurality of semiconductor dies.

17. The semiconductor system of claim 16, wherein a quantity of the two-dimensional array of first contacts is different from a quantity of the two-dimensional array of second contacts.

18. The semiconductor system of claim 16, wherein each of the plurality of semiconductor dies further comprises:
a plurality of second through-substrate vias arranged between respective bank logic of the plurality of memory banks and the respective plurality of memory arrays of the plurality of memory banks,
wherein at least a second subset of the two-dimensional array of second contacts is coupled with the two-dimensional array of first contacts through the plurality of second through-substrate vias of each of the plurality of semiconductor dies.

19. The semiconductor system of claim 16, wherein the two-dimensional array of first contacts are aligned with the two-dimensional array of second contacts through the stack.

20. The semiconductor system of claim 16, further comprising:
a third semiconductor component bonded with the stack, the third semiconductor component comprising:
a two-dimensional array of third contacts along a first side of the third semiconductor component that are coupled with the two-dimensional array of second contacts; and
a plurality of fourth contacts along a second side of the third semiconductor component that are coupled with the two-dimensional array of second contacts, a quantity of the plurality of fourth contacts being less than a quantity of the two-dimensional array of second contacts.

21. The semiconductor system of claim 20, wherein:
the two-dimensional array of second contacts is associated with a first pitch dimension; and
the plurality of fourth contacts is associated with a second pitch dimension that is greater than the first pitch dimension.

22. The semiconductor system of claim 16, wherein the bonding between the plurality of semiconductor dies comprises a fusion of dielectric material portions and a fusion of conductive material portions.

23. A method of forming a semiconductor system, comprising:
bonding a first semiconductor component with a set of one or more second semiconductor components along a first side of the set of one or more second semiconductor components, the first semiconductor component comprising one or more processors of a processing system, and the set of one or more second semiconductor components comprising:
one or more memory arrays accessible by the one or more processors; and
a two-dimensional array of contacts along a second side of the set of one or more second semiconductor components, the contacts coupled with the one or more processors and configured to provide power for operations of the one or more processors.

24. The method of claim 23, further comprising:
bonding a third semiconductor component with the set of one or more second semiconductor components along the second side of the set of one or more second semiconductor components, the third semiconductor component comprising:
a two-dimensional array of second contacts along a first side of the third semiconductor component that are coupled with the two-dimensional array of contacts along the second side of the set of one or more second semiconductor components; and
a plurality of third contacts along a second side of the third semiconductor component that are coupled with the two-dimensional array of second contacts, a quantity of the plurality of third contacts being less than a quantity of the two-dimensional array of second contacts.

25. The method of claim 24, wherein bonding the first semiconductor component with the set of one or more second semiconductor components comprises bonding a front side of one of the set of one or more second semiconductor components with a front side of the first semiconductor component.

26. The method of claim 23, further comprising:
bonding a set of one or more fourth semiconductor components with the first semiconductor component along a first side of the set of one or more fourth semiconductor components, the set of one or more fourth semiconductor components comprising:
one or more second memory arrays accessible by the one or more processors; and
a two-dimensional array of second contacts along a second side of the set of one or more fourth semiconductor components, the second contacts coupled with the one or more processors and configured to provide power for operations of the one or more processors.

27. A method of forming a semiconductor system, comprising:
bonding a plurality of semiconductor dies together in a stack, each of the plurality of semiconductor dies comprising:
a plurality of memory banks each comprising a respective plurality of memory arrays; and
a plurality of through-substrate vias arranged between the plurality of memory banks,
wherein a two-dimensional array of first contacts is arranged on a first surface of the stack, and a two dimensional array of second contacts arranged on a second surface of the stack opposite the first surface, at least a subset of the two-dimensional array of second contacts coupled with the two-dimensional array of first contacts through the plurality of through-substrate vias of each of the plurality of semiconductor dies.

28. The method of claim 27, wherein a quantity of the two-dimensional array of first contacts is different from a quantity of the two-dimensional array of second contacts.

29. The method of claim 27, wherein each of the plurality of semiconductor dies further comprises:
a plurality of second through-substrate vias arranged between respective bank logic of the plurality of memory banks and the respective plurality of memory arrays of the plurality of memory banks,
wherein at least a second subset of the two-dimensional array of second contacts is coupled with the two-dimensional array of first contacts through the plurality of second through-substrate vias of each of the plurality of semiconductor dies.

30. The method of claim 27, further comprising:
bonding a third semiconductor component with the stack, the third semiconductor component comprising:
a two-dimensional array of third contacts along a first side of the third semiconductor component that are coupled with the two-dimensional array of second contacts; and
a plurality of fourth contacts along a second side of the third semiconductor component that are coupled with the two-dimensional array of second contacts, a quantity of the plurality of fourth contacts being less than a quantity of the two-dimensional array of second contacts.
